(19) United States
(12) Patent Application Publication
(10) Pub. No.: US 2015/0301139 A1
(43) Pub. Date: Oct. 22, 2015

(54) METHOD AND SYSTEM FOR INSPECTION OF COMPOSITE MATERIAL COMPONENTS

(71) Applicant: ANATECH ADVANCED NMR ALORITHMS TECHNOLOGIES LTD., Nirit (IL)

(72) Inventors: Alexander SHAMES, Beer-Sheva (IL); Yuri ROZENFELD, Yeruham (IL); David KEINI, Haifa (IL)

(21) Appl. No.: 14/377,349

(22) PCT Filed: Feb. 5, 2013
(86) PCT No.: PCT/IL2013/050108

§ 371 Date: Aug. 7, 2014

Related U.S. Application Data
(60) Provisional application No. 61/596,534, filed on Feb. 8, 2012.

(51) Int. Cl. G01R 33/56; G01R 33/3875; G01R 33/385; G01R 33/34

(52) U.S. Cl. CPC G01R 33/5602; G01R 33/34061; G01R 33/3875; G01R 33/3856

(57) ABSTRACT

A non-destructive inspection of epoxy-based objects by creating a substantially uniform magnetic field of about 0.1 to 0.5 Tesla within a magnetic field region at least partially overlapping with a test zone where the inspected object is to be located, applying electromagnetic excitation signals in the test site to affect the nuclei magnetization in the inspected object and concurrently generating magnetic gradients in three orthogonal directions thereinside, to thereby cause spatially resolved nuclear spin echo signals from the inspected object. Data corresponding to electromagnetic radiation received responsive to the nuclear spin echo signals from the inspected object is processed to extract data indicative of the spatially resolved nuclear spin echo signals from the inspected object, and magnetic resonance images indicative of structural defects in the object are then generated using the extracted data.

### TECHNOLOGICAL FIELD

The present invention relates to techniques for non-destructive testing/evaluation of epoxy-based structural composites (e.g., carbon fibers reinforced epoxy composites), using magnetic resonance imaging (MRI) techniques.

### REFERENCES

References considered to be relevant to the background of the presently disclosed subject matter are listed below:
U.S. Pat. No. 7,176,681 describes a system for non-destructively inspecting a composite material component infiltrated with at least one contrast media by imaging the component with a MRI apparatus to reveal internal and/or external defects of the component.
Japanese Patent Application No. 2000-055844 suggests using ¹³C carbon as a marker for NMR based detection of interlayer of elements and determining the presence or absence of defects, and the degree of the defects.
Götz et al, “Characterization of the Structure in Highly Filled Composite Materials by Means of MRI”, Propellants, Explosives, Pyrotechnics V. 27, 2002, pp. 179-184.
Peeters et al, “Magnetic resonance imaging of microstructure transition in stainless steel”, Magnetic Resonance Imaging V. 24, 2006, pp. 663-672.
A. Kantzas and D. Axelson, “Characterization of Semi-crystalline Polymers Using MRI”, In: Proceedings of 1st World Congress on Industrial Process Tomography, Buxton, Greater Manchester, Apr. 14-17, 1999, pp. 256-263.
Brady et al, “NMR detection of thermal damage in carbon fiber reinforced epoxy resins”, Journal of Magnetic Resonance V. 172, 2005, pp. 342-345.

Acknowledgement of the above references herein is not to be inferred as meaning that these are in any way relevant to the patentability of the presently disclosed subject matter.

### BACKGROUND

High performance epoxy-based composites (EC), particularly carbon fibers reinforced epoxy composites (CFREC), are being increasingly used in aerospace, automotive and biomedical applications. Such materials are lightweight, strong and firm, yet are readily formed into complex shapes. Reliable non-destructive testing/evaluation (NDT/E), and quality control for aerospace/automotive parts manufactured from composite materials is of immense importance, especially for the aerospace industry. Conventional methods of testing and evaluation of such structures, such as X-ray radiography and ultrasonic techniques, encounter difficulties particularly when the inspected objects are thick (e.g., thickness greater than 10-20 mm) and/or when the inspected objects have an intricate geometry.

### General Description

There is a longstanding need for novel non-destructive inspection techniques allowing identifying of structural defects in composite material components (generally referred to herein as objects, or inspected objects) within relatively short durations of time (e.g., from a few minutes to a few hours), and allowing design and cost effective manufacture of inspection devices capable of generating images showing internal and external views of the inspected objects. The present invention provides techniques for non-destructively inspecting structural components made of composite material components for defects utilizing MRI scanning techniques. The techniques of the present invention are particularly useful for inspection of epoxy-based objects containing reinforcing components, such as reinforcing fibers and/or granules. Particularly, the inspection technique of the present invention is carried out in some embodiments using proton (¹H) magnetic resonance imaging (MRI) techniques performed with magnetic fields having relatively low intensities (e.g., in the range of 0.1 to 0.5 Tesla).

The inventors of the present invention have surprisingly found that internal and external defects of a structural component made of epoxy-based composite materials may be identified using direct 2D/3D proton MRI scanning (e.g., using solid state MRI apparatus) employing relatively low constant magnetic fields and relatively low frequency (about 5 to 25 MHz wave band) excitation signals. Notably, the MRI inspection techniques of the present invention do not require prior filling/infiltration of the inspected objects with liquid or gas contrast media, or using any marker additives or isotope enrichment, as used in some of the prior art publications.

The inspection may be carried out using a MRI scanning system comprising a MRI test chamber having a test zone in which the inspected object is to be placed. A magnetic field source unit is provided in the MRI test chamber to create a magnetostatic field in the range of 0.1 to 0.5 Tesla in a magnetic field region in the test zone (e.g., using “C”-shaped or “G”-shaped permanent magnet assembly), to thereby magnetize nuclei in the inspected object. The magnetic field source unit is configured and operable to apply a constant magnetic field having sufficient homogeneity of about 10-20 ppm in the test volume.

The MRI test chamber further comprises an inductive coil placed inside said test zone and configured and operable to surround the inspected object placed therein, apply radiofrequency (RF) excitation pulses inside the test zone to thereby affect the magnetization of the nuclei of the inspected object, and to generate an electromagnetic response to nuclear spin echo signals from the inspected object. A set of gradient coils may be situated inside the test zone for generating magnetic gradients in three orthogonal directions thereinside and thereby spatially encode the nuclear spin echo signals from the inspected object responsive to the applied excitation pulses.

Accordingly, in some embodiments the MRI scanning system comprises a signal generating unit configured and operable to generate the RF excitation pulses and to feed them to the inductive coil, and a receiver unit configured and operable to receive the electromagnetic response of the at least one inductive coil and generate measured data indicative thereof. A controllable switching device (e.g., duplexer) may be used to controllably communicate the RF excitation pulses generated by the signal generating unit to the inductive coil during signal excitation sessions, and to controllably communicate the electromagnetic response from the inductive coil to the receiver unit during signal acquisition sessions. A gradient generator may be used for generating gradient currents used by the gradient coils for generating the magnetic gradients used to spatially encode/decode the nuclear spin echo signals.

The inspection process thus comprises applying short (e.g., 0.5-2 μs) electromagnetic excitation pulses in directions perpendicular to the direction of the applied constant magnetic field, and concurrently generating the magnetic gradients, inside the MRI test chamber in which the object is placed for inspection, to excite spatially encoded nuclear spin echo signals from proton nuclei of the inspected object. The electromagnetic excitation pulses therefore may have a frequency within the radio frequency band chosen to satisfy resonance conditions (e.g., in the range of 5 to 25 MHz).

The MRI system further comprises a control unit for operating the signal generating unit, the controllable switching device and the gradient generator, to provide predetermined time patterns of the generation of the excitation RF signals and of the receipt of the electromagnetic response. The control unit is further configured and operable to process the measured data and extract data indicative of the spatially encoded nuclear spin echo signals from the inspected object and generate magnetic resonance images based thereon. In some possible embodiments the control unit is further adapted to inspect the generated magnetic resonance image and identify irregularities in said images indicative of structural defects in the inspected objects.

Accordingly, there is thus provided a system for non-destructive inspection of epoxy-based objects employing proton magnetic resonance imaging. The system comprises a signal generating unit configured and operable for generating pulsed RF excitation signals (e.g., in the range of 5 to 25 MHz), a gradient generator for generating gradient signals, and an MRI testing chamber defining a test zone (e.g., having a volume of about 0.001 to 0.2 m³) for the inspected object. The MRI testing chamber comprises a magnetic field source unit configured and operable to generate a substantially uniform magnetic field of about 0.1 to 0.5 Tesla in a magnetic field region in which said test zone is located, to thereby magnetize nuclei in the inspected object. Gradient coils placed inside the test zone are used for generating magnetic field gradients in three orthogonal directions in the test zone responsive to the gradient currents from the gradient generator, to thereby spatially affect the nuclei magnetization of the inspected object.

At least one inductive coil is used inside the test zone, the coil being configured and operable to surround the inspected object so as to be in the magnetic field region and to be exposed to the excitation signals, the inductive coil being configured to surround at least a part of the inspected object when placed in said test zone. The at least one inductive coil thus responds to the magnetic field and to the RF excitation signals by generation of electromagnetic excitation signals in directions substantially perpendicular to a direction of the magnetic field to thereby affect the nuclei magnetization in the inspected object, and generate an electromagnetic response to nuclear spin echo signals from the inspected object.

The system further comprises a receiver unit configured and operable to receive the electromagnetic response of the at least one inductive coil and generate measured data indicative thereof.

A control unit is used for operating the signal generating unit and the gradient generator, to provide predetermined time patterns of the generation of the excitation RF signals of the gradient signals and of the receipt of the electromagnetic response. The control unit is configured and operable to process the measured data and extract data indicative of the nuclear spin echo signals from the inspected object and generate magnetic resonance images based thereon.

The system may comprise a controllable switching device configured and operable to controllably switch between communicating of the excitation signals from the signal generator to the inductive coil, and communicating of the electromagnetic response from the inductive coil to the receiver unit. In addition, the system may comprise a controllable signal source for generating excitation signals and demodulating signals having radiofrequencies in the range of 5 to 25 MHz.

In some embodiments the signal generating unit comprises a RF pulse generator configured and operable to use the excitation signals from the controllable signal source for generating RF excitation pulse sequences for use in the pulsed RF excitation signals.

The receiver unit comprises in some embodiments a quadrature modulator unit configured and operable to use the demodulating signals from the controllable signal source to demodulate the electromagnetic response, and decompose the demodulated signal into in-phase and quadrature components. Accordingly, the system may comprise a two channel analog to digital converter for digitizing the in-phase and quadrature components from the quadrature modulator unit.

In applications the control unit is configured and operable to generate the magnetic resonance images by processing the nuclear spin echo signals as follows: carrying out time domain processing for digital filtering and instrumental artifacts removal; frequency domain processing for transforming the signals into the frequency domain; and k-space processing for transforming k-space data into spatially resolved 2D and 3D magnetic resonance images. The control unit may be further configured and operable to extract from the magnetic resonance images characteristic features associated with structural defects in the inspected object (e.g., using proton density images and relaxation contrast images).

In some possible embodiments the magnetic field source unit comprises a permanent magnet assembly (e.g., comprising rare-earth hard magnetic materials, such as, but not limited to SmₓCo_{y} and NdFeB alloys) configured and operable to generate the substantially uniform magnetic field between a pair of magnetic poles thereof in a predetermined direction within the test zone. Optionally, the magnetic field source unit comprises a set of Helmholtz coils configured and operable to correct temperature drifts and homogeneity of the magnetic field. The magnet assembly may be configured in a form of “G”-shape or “C”-shape structure.

In some applications the inspected object is reinforced by fibers, or granules, made from one or more materials selected from the following group: glass, boron, silicon carbide, carbon, and metal. Additionally or alternatively, the inspected object comprises nuclear probes comprising materials having high natural abundance (e.g., comprising ¹⁹F, ²⁷Al and/or ³¹P isotopes).

According to another aspect there is provided a method for non-destructive inspection of an epoxy-based object. The method comprises creating a substantially uniform magnetic field of about 0.1 to 0.5 Tesla within a magnetic field region at least partially overlapping with a test zone where the inspected object is to be located, to thereby magnetize nuclei in the object, applying electromagnetic excitation signals (e.g., comprising gradient echo, spin echo and/or inversion recovery pulse sequences) in the test site to thereby affect the nuclei magnetization in the inspected object and concurrently generating magnetic gradients in three orthogonal directions thereinside, to thereby cause spatially resolved nuclear spin echo signals from the inspected object, the electromagnetic excitation signals being applied with a predetermined time pattern, receiving, with a predetermined time pattern, electromagnetic radiation responsive to the nuclear spin echo signals from the inspected object, processing data corresponding to the received electromagnetic radiation, to extract therefrom data indicative of the spatially resolved nuclear spin echo signals from the inspected object, and using the extracted data to generate magnetic resonance images indicative of structural defects in said object.

The method may further comprise displaying the magnetic resonance images in a display device and inspecting the displayed magnetic resonance images to indentify structural defects in said object. Additionally or alternatively, the method may comprise extracting from the magnetic resonance images characteristic features associated with the structural defects in the inspected object, identifying in the magnetic resonance images structural defects of the inspected object, and outputting signals indicating that such structural defects been identified. For example, in some embodiments T₁-weighting and/or T₂-weighting techniques are used for contrasting the magnetic resonance images for revealing specific defects therein.

In some applications the inspected object is reinforced by fibers, or granules, made from one or more materials selected a group consisting of: glass, boron, silicon carbide, carbon, and metal.

Optionally, the excitation signals are selected so as to affect magnetization of one or more nuclei selected from the following group: ¹H, ¹³C.

Advantageously, the inspection of the object is carried out without using contrast media or marker additives.

The method may comprise embedding in the inspected object nuclear probes having high natural abundance (e.g., comprising one or more isotopes selected from the group consisting of: ¹⁹F, ²⁷Al and ³¹P).

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 schematically illustrates a MRI test chamber usable for object inspection techniques according to some embodiments;

FIG. 2 is a block diagram of an object inspection system according to some embodiments utilizing the MRI test chamber shown in FIG. 1; and

FIG. 3 is a flowchart exemplifying an object inspection process according to some possible embodiments.

### DETAILED DESCRIPTION OF EMBODIMENTS

The present invention provides novel inspection techniques for non-destructive testing/evaluation of structural components made of EC, particularly of CFREC, using magnetic resonance imaging (MRI). The inspection techniques of the present invention permits identification of internal and external defects of a structural component made of CE/CFREC by direct 2D/3D MRI scanning of the epoxy-based structural components. In particular, in some embodiments a solid state MRI system is used for scanning the structural components employing a constant magnetic field having a relatively low intensity and electromagnetic excitation signals having relatively low frequencies, without prior filling/infiltration by liquid or gas contrast media and/or adding markers additives to the inspected structural components.

Most modem composite materials consist of large amounts of epoxy resins, binders etc., Thus proton (¹H) nuclear magnetic resonance (NMR) imaging (know as MRI) offers a viable potential for more reliable NDT/E of these composite material objects, since the image obtained using these techniques is independent of the thickness and/or shape of the inspected object. It is a principal object of the present invention to utilize MRI scanning techniques for NDT/E detection of defects such as voids, delamination and inter-laminar cracks in the manufactured composite material objects, either as made or after a repair.

The inspection techniques disclosed herein are based on the fact that various composite materials (e.g., as used in aerospace applications) are based on epoxy resins. Epoxy resin is the main matrix component for a myriad of reinforced composite materials. Epoxy resin, disregarding the type of reinforcing elements (if at all) used, contains many protons with quite narrow NMR lines. These protons are used in the inspection technique of the present invention for obtaining 2D/3D magnetic resonance (MR) images of the interiors and/or exterior surfaces of composite structural elements. Proton images also allow using special pulse sequences for contrasting of specific defects (e.g., utilizing T₁ weighting, or T₂ weighting). The techniques disclosed herein are not limited to any specific contrasting pulse sequence, such that various different contrasting pulse sequences may be used to enhance the MR images of in the inspected objects (e.g., as described by Bitar R. et al., RadioGraphics 2006; 26:513-537).

Though difficulties may arise in direct imaging of polymer matrices of composite materials, due to the intrinsic NMR properties of these materials, proper analysis of the NMR images generated using magnetic field gradients allows detection of defects in the inspected objects (C. Nicholls, Introduction to NMR methods in NDT, IEE Colloquium on NMR/MRI used in NDT, 1994, pp. 1/1-1/3; N. J. Clayden, Non destructive testing of thermoplastic composites by NMR imaging, IEE Colloquium on NMR/MRI used in NDT, 1994, pp. 3/1-3/2). Currently, NMR imaging is rarely used in non-destructive evaluation and testing for structural defects of composite material components. The reasons for this can be found in the high capital costs of NMR equipment, widespread lack of understanding of the technique and its capabilities, and perhaps most importantly, the conservative nature of the industry, where existing programs are firmly established using proven traditional methods.

The most costly and delicate component of conventional MRI scanners is its magnet assembly used to apply homogeneous persistent magnetic fields across the scanned area. Higher magnetic field strength values (above 1 T) mean higher sensitivity of the MRI scanner, but also entail use of higher resonance radio frequencies (RF e.g., above 40 MHz) and more costly magnets having medium/large homogeneous field volume. However, most of the CFREC based objects are characterized by a high abundance of conducting amorphous carbon and/or graphite fibers, and as a result high RF excitation signals typically do not penetrate objects made of CFREC, which therefore exclude using conventional high field high frequency MRI instruments for NDT/E purposes.

On the other hand, the inventors of the present invention surprisingly found that RF excitation signals below 20 MHz provide acceptable penetration through composite materials, 60-70% of their weight is made of carbon fibers (i.e., a high abundance of graphite). Thus, in some embodiments, MRI inspection of composite objects is performed using a MRI scanner employing RF excitation signals having radiofrequencies smaller than 20 MHz and corresponding constant magnetic field intensities smaller than 0.5 Tesla. Establishing such relatively low intensity magnetic fields with acceptable homogeneity within a medium/large test volume may be achieved using energy independent permanent magnets equipped with low energy consuming Helmholtz coils for correction of temperature drifts and a set of shimming coils for improving homogeneity.

It is noted that the use of magnetic fields having relatively low intensities in the MR imaging techniques of the present application further allows significant penetration of the probing RF signals into graphite reinforced composites components, for which MR imaging inspection techniques are generally considered to be inappropriate, due to the electrical conductivity of the graphite fiber/granules.

A significant drop in sensitivity due to the use of relatively low intensity magnetic fields may be compensated by using special spin echo (SE) signal acquisition techniques (e.g., such as multiple SE signal collection), newly developed algorithms for low signal-to-noise processing algorithms, and suchlike. For instance, acquiring solid-state SE signals with multiple frequency selective excitation of broad (short T₂) NMR lines in solid EC/CFREC at optimal pulse repetition rate permits improving useful signals within the same scanning period. Problems associated with a decrease in resolution due to relatively broad resonance lines in solids requires using strong magnetic field gradients as well as implementation of various advanced techniques of spatial encoding/decoding of proton density MRI images (e.g., as described by McDonald et al, “A new approach to the NMR imaging of solids”, Journal of Magnetic Resonance V. 72, 1987, pp. 224-229; Cory et al, “Time suspension multiple pulse sequences: application to solid-state imaging”, Journal of Magnetic Resonance V. 90, 1990, pp. 205-213; Demco et al, “Spatially resolved homonuclear solid-state NMR.III. Magic-echo and rotary-echo phase encoding-imaging”, Journal of Magnetic Resonance V. 96, 1992, pp. 307-322; Frey et al, “Phosphorus-31 MRI of hard and soft solids using quadratic echo line-narrowing”, Proceedings of the National Academy of Sciences of the United States of America, V. 109, N. 14, 2012, pp. 5190-5195.)

The techniques disclosed herein enables to acquire interior images of composite objects using MRI based techniques, even for objects made of carbon (graphite) reinforced epoxy resins. Graphite fibers are most popular in use in epoxy based composite objects, and also the most problematic for inspection, due to poor penetration of RF signals to the inside of the graphite reinforced composite objects. Clearly, if the RF excitation signals do not penetrate the inspected object, it is impossible to get any information or image from the inside nuclei (even for the most abandoned ¹H, and particularly in the case of ¹³C). The inventors of the present invention found that low frequency excitation electromagnetic signals (e.g., having radiofrequencies smaller than 20 MHz) well penetrate graphite reinforced epoxy. The techniques disclosed herein permit using MRI scanners employing magnetic fields having relatively low intensities and electromagnetic excitation signals having relatively low radiofrequencies for NDT inspection of such graphite reinforced epoxy objects.

A further important feature of the present invention relates to the significant (more than an order of magnitude) shortening of spin-lattice relaxation times T₁ of the epoxy resin protons due to the use of a magnetic field having relatively low intensities and electromagnetic excitation signals having relatively low radiofrequencies in the MRI scanning. Due the significantly shorter spin-lattice relaxation times, it is possible to compensate for the decrease in sensitivity (due to the use of magnetic fields of relatively low intensities) by using shorter acquisition delays and using a plurality of excitation and respective acquisition cycles to improve the signals to noise ratios of the acquired signals. This enables acquiring MRI images significantly of the same quality as obtained with MRI scanners utilizing strong magnetic fields (i.e., in the range of 0.7 to 7 Tesla) within the same (or even shorter) test times (e.g., in the range of a few minutes to a few hours).

Further advantages of the techniques of the present invention permit using less costly permanent magnet assemblies, less strict requirements of field homogeneity, and use of standard gradient current supplies for applying field gradients in the MRI test chamber, which significantly decrease the costs of the NDT/MRI inspection system employing the techniques of the present invention.

In some possible embodiments a shielded MRI test chamber having a medium/large test zone (e.g., about 0.001 to 0.2 m³) is used in a MRI solid state scanner system configured to generate MR images of an inspected composite material object (e.g., epoxy based, and/or other constituents of EC/CFREC) by employing magnetic fields of relatively low intensities, and magnetic field gradient generation techniques suitable for obtaining spatially resolved nuclear spin echo signals from nuclei of the inspected object.

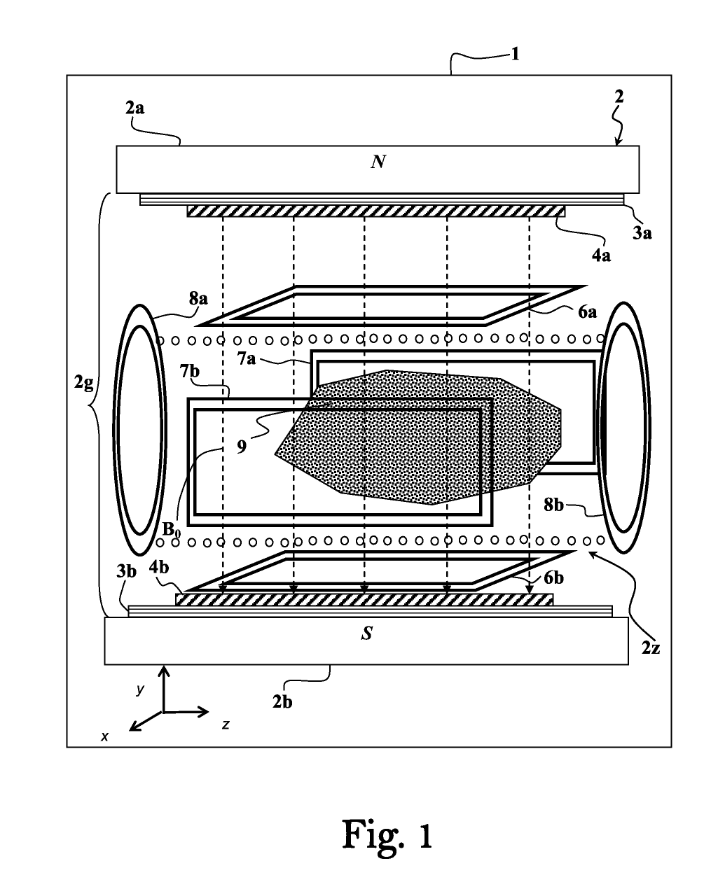

FIG. 1 schematically illustrates a possible configuration of a shielded MRI test chamber 1 usable for the NDT MRI scanning according to some possible embodiments. MRI test chamber 1 includes a permanent magnet assembly 2 having “N” and “S” poles, 2a and 2b respectively, defining a test zone 2z therebetween. The test zone 2z in some embodiments may be configured as a medium/large volume (e.g., about 0.001 to 0.2 m³) configured to accommodate inspected objects 9 made from a composite material (e.g., epoxy) thereinside. The magnet assembly 2 is configured and operable to generate a constant and substantially homogeneous magnetic field B₀ inside the test zone 2z for magnetizing nuclei (e.g., of the epoxy resin matrix) of the inspected object 9.

The magnet assembly 2 may be configured as a “C”-shaped or “G”-shaped magnet structure made of samarium cobalt or neodymium-iron-boron alloys, configured to generate a magnetostatic field B₀ having a relatively low strength (e.g., in the range of 0.1 to 0.5 T). The gap 2g between the poles 2a and 2b of the magnet assembly 2 may generally be in the range of 0.1 to 1 meters, preferably about 0.5 meters, and in such configurations the magnetostatic field B₀ obtained is generally about 0.2-0.3 T.

In this example the magnetostatic field B₀ is generated in the y-direction within a gap 2g sufficient to accommodate the inspected object. The MRI test chamber 1 further comprises a transmitter/receiver coil, or an array of coils (e.g., comprising up to 16 single coils 3) situated in the test zone 2z between the magnetic poles 2a and 2b, and configured and operable to accommodate the inspected object 9, or a portion thereof, within its (their) coil turns.

In some embodiments the MRI test chamber 1 further includes a pair of Helmholtz coils 3a and 3b, and a set of shimming coils 4a and 4b, located in the test zone 2z, and configured and operable to accommodate the inspected object 9 and transmitter/receiver and gradient coils. The Helmholtz coils 3a and 3b are used for correcting temperature drifts of the permanent magnet assembly 2, and the shimming coils 4a and 4b for improving homogeneity of the permanent magnet assembly 2.

A set of gradient coils 6a, 6b, 7a, 7b, 8a and 8b, is used in the MRI test chamber 1, the gradient coils configured and operable to enable generation of magnetic gradients in three orthogonal directions inside the MRI test chamber 1. More particularly, the gradient coils 6a and 6b are configured and operable to generate magnetic gradients in the y-direction, the gradient coils 7a and 7b are configured and operable to generate magnetic gradients in the x-direction, and the gradient coils 8a and 8b are configured and operable to generate magnetic gradients in the z-direction.

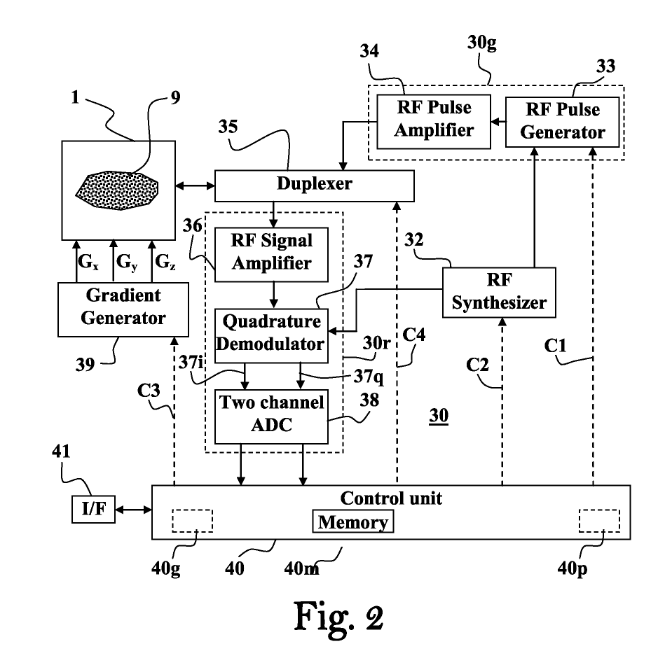

FIG. 2 is a block diagram showing a MRI inspection system 30 according to some possible embodiments. The MRI system 30 comprises the shielded MRI test chamber 1 designed to accommodate the inspected object 9 inside its test zone (2z), excitation signal generating block 30g, a signal receiving block 30r, a duplexer unit 35 for communicating between the shielded MRI test chamber 1 and the signal generating block 30g in excitation session and the receiving block 30r in acquisition sessions, and a fast switchable phase controlled RF synthesizer unit 32 for generating signals having relatively low radiofrequencies (e.g., in the range of 5 to 25 MHz).

The system 30 further comprises a gradient generator 39 electrically connected to the gradient coils 6a, 6b, 7a, 7b, 8a and 8b, of the MRI test chamber 1, a control unit 40 configured and operable to generate control signal for operating the units/blocks of system 30, process signals received through the signal receiving block 30r, and a user interface 41 configured and operable to display MRI images received from the control unit 40 and receive user inputs and transfer data indicative thereof to the control unit 40.

The excitation signal generating block 30g comprises a RF pulse generator 33 configured and operable for using signals generated by the RF synthesizer unit 32 for generating pulses of radiofrequency signals, and a RF pulse power amplifier 34 for amplifying the RF pulses from the RF pulse generator 33 and transferring the same to the duplexer unit 35 for transmission through the receive/transmit coil(s) 3 of the MRI test chamber 1. The signal receiving block 30r comprises a RF signal amplifier 36 for amplifying relaxation signals received by the receive/transmit coil(s) 3 of the MRI test chamber 1, a quadrature demodulator unit 37 for demodulating the amplified signals from the RF signal amplifier 36 and generating in-phase (37i) and quadrature (37q) components thereof, a two channel analog to digital converter (ADC) 38 for digitizing the in-phase (37i) and quadrature (37q) signals from the demodulator unit 37 and providing the same to the control unit 40. In excitation sessions the control unit 40 issues control signals C2 to operate the RF synthesizer unit 32 for generating signals having a desired excitation frequency and phase, and control signals C1 instructing the RF pulse generator 33 to use the signals from the RF synthesizer unit 32 for generation of a predefined sequence of RF excitation pulses having predetermined time durations and delay times therebetween. The control unit 40 further issues control signals C4 to operate the duplexer 35 to communicate the sequence of RF excitation pulses from the signal generating block 30g to the receive/transmit coil(s) 3 of the MRI test chamber 1. The control signals C3, also issued by control unit, operate the gradient generator 39 to generate magnetic gradient signals, Gₓ, G_{y} and G_{z}, used by the gradient coils (4a, 4b), (5a, 5b), and (6a, 6b) for generating gradient magnetic fields along the x, y, and z directions inside the MRI test chamber 1, and thereby cause spatially resolved (i.e., obtained from the specified resonating volume —voxel, which is determined by magnetic field gradients applied) nuclear spin echo signals from the inspected object.

In the acquisition sessions, the control unit 40 issues control signals C4 for operating the duplexer 35 to communicate the relaxation signals received by receive/transmit coil(s) 3 to the signal receiving block 30r, and control signals C2 for operating the RF synthesizer unit 32 to generate signals having frequencies (e.g., in the range of 5 to 25 MHz) suitable for demodulating the signals received from the receive/transmit coil(s) 3. The relaxation signals transferred through the duplexer 35 to the signal receiving block 30r are first amplified by the RF signal amplifier 36, demodulated by the quadrature demodulator unit 37, and the in-phase (37i) and quadrature (37q) components produced by the quadrature demodulator unit 37 are then digitized by the two channel ADC unit 38. The digitized data from the ADC unit 38 are transferred to the control unit 40 for processing and generation of MR images of the inspected object 9.

In order to quickly switch between the excitation and acquisition sessions the RF synthesizer unit 32 is configured to quickly switch between generations of phased controlled excitation frequencies and generations of phased controlled demodulation frequencies. For example, in some embodiments the delay time between consecutive excitation and acquisition sessions may be about 0.1 to 2 seconds and the RF synthesizer unit 32 is thus designed as a fast switchable phased controlled synthesizer unit in order to permit the system to quickly change between the excitation and acquisition operation modes.

The control unit 40 may comprise one or more memories 40m for storing program code and data used for operating the system 30, for processing the signals received from the signal receiving block 30r, and for generating the MR images and communicating MR image data to the user interface unit 41. For example, the control unit may comprise a pulse controller module 40p configured and operable for generating the control signals C1 used by the control unit 40 for operating the RF pulse generator 33. The control unit 40 may further comprise a gradient controller module 40g configured and operable for generating the control signals C3 used by the control unit 40 for operating the gradient generator unit 39. The control unit 40 may comprise various additional modules usable for generating the control signals C2 and C4, for example, and for processing the received signals and communicating data with external devices, such as the user interface 41.

The user interface 41 may comprise a graphical display (e.g., CRT/LED based monitor—not shown), communication ports (e.g., USB and/or wireless—not shown) configured and operable to communicate data related to the inspection of objects and the obtained results (e.g., for presentation in a portable device such as PDA, tablet or smartphone, and/or for storage in a databases maintained on an external storage device such as a database server).

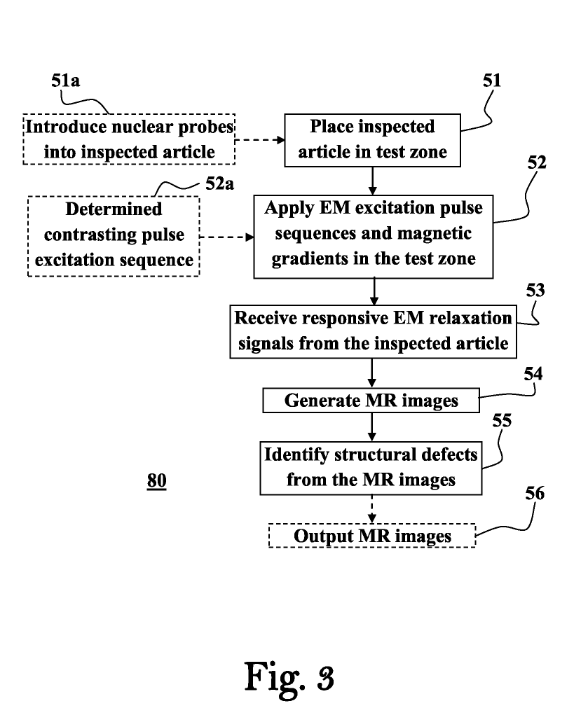

FIG. 3 is a flowchart of a possible object inspection process 80 according to some possible embodiments. The process 80 begins in step 51 by placing the inspected object (9) in the test zone (2z) of the MRI test chamber 1, thereby exposing it to the magnetic field (B₀) and magnetizing nuclei of the inspected object. Optionally, in some possible embodiments, in step 51a nuclear probes comprising materials having high natural abundance are embedded in the resin matrix of the inspected object to improve the spin echo signals from the inspected object. In step 52, one or more electromagnetic excitation pulse sequences and magnetic field gradients are applied in the test zone to affect the magnetization of the inspected object nuclei. In some possible embodiments, optional step 52a is carried out for determining suitable contrasting pulse excitation sequences to be used in the probing step 52.

In step 53 responsive electromagnetic relaxation signals from the inspected article are received via the coil 3, and in step 54 the received relaxation signals are for generating MR images of the inspected object.

Next, in step 55, the existence of structural defects in the inspected object is determined using manual or automated techniques. For example, in some possible embodiments the generated MR images are displayed in a display device for human eye inspection to allow a user of the system to determine if there are any defects in the inspected object. Alternatively, the system may be adapted to automatically identify defects in the inspected object using suitable image processing and/or pattern recognition algorithms may be used for scanning the generated MR images and identifying in them irregularities indicative of defects.

Finally, in optional step 56, the generated MR images are transferred to an external storage device, and/or computer system for further analysis and/or display.

It is noted that in the inspection of epoxy based objects the source of high quality 2D/3D magnetic resonance images is the protons (¹H nuclei) of the epoxy resin matrix. Accordingly, all reinforcing elements, defects, voids and interior structure, of the epoxy resin matrix will be seen in the generated proton density MR images.

It is further noted that MR proton images also allow using special pulse sequences for contrasting of specific defects. Furthermore, all MR images are to some degree affected by each of the parameters that determine contrast (i.e., spin-lattice relaxation time T₁, spin-spin relaxation time T₂, and proton density), but the delay times between excitation pulses can be adjusted to emphasize a particular type of contrast. This may be done, for example, utilizing T₁ or T₂ weighting. In T₁-weighted and T₂-weighted MR imaging, while the images show all types of contrasts, T₁ contrasts or T₂ contrasts are accentuated. For instance, protons in the vicinity of paramagnetic defects, concerned mostly with graphite fibers, will have much shorter T₁ and T₂ values. By properly adjusting different parameters of MR imaging pulse sequences, it is possible to contrast and distinguish between various types of defects.

### EXAMPLES

### Example 1

Samples of real pure epoxy resin used in composite components for aerospace industry were studied by ¹H broad line solid state NMR at high (8.0196 Tesla by wide bore commercial Oxford Instruments superconducting magnet, at f₀=341.41 MHz) and low (0.2730 Tesla by electromagnet from a commercial Varian E-12 EPR spectrometer, at f₀=11.62 MHz) magnetic fields intensities aiming to test the applicability of MRI from ¹H nuclei of the epoxy resin to provide images of the interior of epoxy based objects. Solid epoxy samples of 4 mm×4 mm×28 mm size and 0.3973 g weight were placed into 5 mm i.d. coils of the correspondingly tuned NMR probe. Spectra were obtained using commercial Tecmag Libra NMRkitII pulsed NMR spectrometer by Fourier transformed signals of solid spin echoes. The use of the solid echo excitation technique instead of Hahn echo conventionally used for liquid NMR, increases the intensity of the spin echo signal at least by a factor of two. Spin-lattice relaxation times T₁ were measured by combined inversion recovery-spin echo (for high magnetic field inspection) and progressive saturation-spin echo (for low magnetic field inspection) techniques. Spin-spin relaxation times T₂ were measured using a spin echo decay technique.

Spectra at both frequencies show strong broad (˜35 kHz full width at half height) Gaussian-shaped lines easily detected by pulsed NMR. No probe detuning and no NMR signal attenuation were found for pure epoxy resin samples. The relaxation times obtained were T₁=980±110 ms, and T₂˜30 μs for the high magnetic field intensity inspection at f₀=341.41 MHz, and T₁=72±4 ms and spin-spin relaxation T₂=32.4±0.1 μs for the low magnetic field intensity inspection at f₀=11.62 MHz. These measurements demonstrate applicability of ¹H MRI to the composite components consisting mainly of epoxy: NMR signals are strong enough and there is no RF attenuation through the sample at both high and low frequency.

Notably, significant (more than order of magnitude) shortening of the spin lattice relaxation time T₁ in working at low magnetic field intensities indicates applicability of low field NMR machines to generate quality MR images within shorter signal acquisition times that should compensate for the reduction in sensitivity due to switching to low magnetic field intensities.

### Example 2

Real composite components used in the aerospace industry are usually reinforced by various threads, fibers and other fillers. From the point of view of the applicability of MRI from ¹H nuclei of the epoxy resin, as the main source of images, serious problems may be found just for graphite fiber reinforced epoxy resins. These samples possess local conductivity and strong dielectric losses. These features may cause strong attenuation of probing RF irradiation used in MRI making it inapplicable for inspection of such composite components.

In this example, solid samples of real graphite fiber reinforced epoxy resin used in composite components for the aerospace industry were studied by ¹H broad line solid state NMR at high (8.0196 Tesla, by wide bore commercial superconducting magnet, at f₀=341.41 MHz) and low (0.2730 T by electromagnet from a commercial EPR spectrometer, f₀=11.62 MHz) magnetic field intensities using the same setup as in Example 1. Graphite fiber reinforced epoxy samples of 4×4×8 mm size and 0.1301 g weight (high magnetic field intensity at f₀=341.41 MHz) and 4×4×28 mm size and 0.4345 g weight (low magnetic field intensity, at f₀=11.62 MHz) were placed in a 5 mm i.d. coils of the correspondingly tuned NMR probe. Spectra were obtained by Fourier transformed signals of solid spin echoes. The use of the solid echo excitation technique instead of the Hahn echo technique conventionally used for liquid NMR increases the intensity of the spin echo signal at least by a factor of two. Spin-lattice relaxation times T₁ were measured by combined inversion recovery-spin echo (for the high magnetic field inspection) and progressive saturation-spin echo (for the low magnetic field inspection) techniques. Spin-spin relaxation times T₂ were measured employing spin echo decay technique.

Spectra at both frequencies show strong broad (˜30 kHz full width at half height) Gaussian-shaped lines easily detected by pulsed NMR. Strong probe detuning and NMR signal attenuation were found for the graphite fiber reinforced epoxy resin samples inspected at high magnetic field intensity (at f₀=341.41 MHz). No probe detuning and no NMR signal attenuation were found for the graphite fiber reinforced epoxy resin samples at low magnetic field intensity (at f₀=11.62 MHz). The relaxation times obtained were T₁=900±100 ms and T₂˜30 is (for high magnetic field intensity, at f₀=341.41 MHz) and T₁=54±7 ms and spin-spin relaxation T₂=30.7±0.2 μs (for low magnetic field intensity, at f₀=11.62 MHz).

These measurements demonstrate applicability of low magnetic field ¹H MRI for inspection of composite components consisting mainly of epoxy: NMR signals are strong enough and no RF attenuation through the sample at frequencies below 15-20 MHz. Significant (more than an order of magnitude) shortening of the spin lattice relaxation time T₁ on working at low magnetic field intensities indicates applicability of low magnetic field intensity NMR machines to obtain quality MR images within shorter signal acquisition times that should compensate for reduction in sensitivity due to switching to low magnetic field intensities. On the other hand, high magnetic field intensity ¹H MRI may be quite problematic for these graphite fiber reinforced samples due to strong detuning and attenuation of both excitation RF pulses and response NMR signals.

The above examples and description have of course been provided only for the purpose of illustration, and are not intended to limit the invention in any way. As will be appreciated by the skilled person, the invention can be carried out in a great variety of ways, employing more than one technique from those described above, all without exceeding the scope of the invention.

1. A system for non-destructive inspection of epoxy-based objects employing proton magnetic resonance imaging, the system comprising:
a signal generating unit configured and operable for generating pulsed RF excitation signals;
a gradient generator for generating gradient currents;
an MRI testing chamber defining a test zone for the inspected object and comprising:
a magnetic field source unit configured and operable to generate a substantially uniform magnetic field of about 0.1 to 0.5 Tesla in a magnetic field region in which said test zone is located, to thereby magnetize nuclei in the inspected object;
gradient coils placed inside said test zone for generating magnetic gradients in three orthogonal directions is said test zone responsive to the gradient signals from the gradient generator to thereby spatially affect the nuclei magnetization of the inspected object;
at least one inductive coil placed inside said test zone configured and operable to surround the inspected object so as to be in the magnetic field region and to be exposed to the excitation signals, the inductive coil being configured to surround at least a part of the inspected object when placed in said test zone, said at least one inductive coil thereby responding to said magnetic field and said RF excitation signals by generation of electromagnetic excitation signals in directions substantially perpendicular to a direction of said magnetic field to thereby affect the nuclei magnetization in the inspected object, and generating an electromagnetic response to nuclear spin echo signals from the inspected object;
a receiver unit configured and operable to receive said electromagnetic response of the at least one inductive coil and generate measured data indicative thereof; and
a control unit for operating the signal generating unit and the gradient generator, to provide predetermined time patterns of the generation of the excitation RF signals of the gradient signals and of the receipt of the electromagnetic response, said control unit being configured and operable to process the measured data and extract data indicative of the nuclear spin echo signals from the inspected object and generate magnetic resonance images based thereon.

2. The system according to claim 1 comprising a controllable switching device configured and operable to controllably switch between communicating of the excitation signals from the signal generator to the inductive coil, and for communicating the electromagnetic response from the inductive coil to the receiver unit.

3. The system according to claim 1 comprising a controllable signal source for generating excitation signals and demodulating signals having radiofrequencies in the range of 0.5 to 25 MHz.

4. The system according to claim 3, wherein the signal generating unit comprises a RF pulse generator configured and operable to use the excitation signals from the controllable signal source for generating RF excitation pulse sequences for use in the pulsed RF excitation signals.

5. The system according to claim 3, wherein the receiver unit comprises a quadrature modulator unit configured and operable to use the demodulating signals from the controllable signal source to demodulate the electromagnetic response, and decompose the demodulated signal into in-phase and quadrature components.

6. The system according to claim 5 comprising a two channel analog to digital converter for digitizing the in-phase and quadrature components.

7. The system according to claim 1 wherein the control unit is configured and operable to generate the magnetic resonance images by processing the nuclear spin echo signals as follows: carrying out time domain processing for digital filtering and instrumental artifacts removal; frequency domain processing for transforming the signals into the frequency domain; and k-space processing for transforming k-space data into spatially resolved 2D and 3D magnetic resonance images.

8. The system according to claim 1 wherein the control unit is further configured and operable to extract from the magnetic resonance images characteristic features associated with structural defects in the inspected object using proton density images and relaxation contrast images.

9. The system according to claim 1 wherein the geometrical dimensions of the test zone are about 0.001 to 0.2 m³.

10. The system according to claim 1 wherein the magnetic field source unit comprises a permanent magnet assembly configured and operable to generate the substantially uniform magnetic field between a pair of magnetic poles thereof in a predetermined direction within the test zone.

11. The system according to claim 10 wherein the magnetic field source unit comprises a set of Helmholtz and shimming coils configured and operable to correct temperature drifts and homogeneity of the magnetic field.

12. The system according to claim 10 wherein the permanent magnet assembly comprises rare-earth hard magnetic materials.

13. The system according to claim 12 wherein the rare-earth hard magnetic materials comprise one or more of SmₓCo_{y} and NdFeB alloys.

14. The system according to claim 10 wherein the permanent magnet assembly has “G”-shape or “C”-shape structure.

15. The system according to claim 1 wherein the inspected object is reinforced by fibers, or granules, made from one or more materials selected from the following group: glass, boron, silicon carbide, carbon, and metal.

16. The system according to claim 1 wherein the inspected object comprises nuclear probes comprising materials having high natural abundance.

17. The system according to claim 16 wherein the nuclear probes comprise one or more isotopes selected from the group consisting of: ¹⁹F, ²⁷Al and ³¹P.

18. A method for non-destructive inspection of an epoxy-based object, comprising:
creating a substantially uniform magnetic field of about 0.1 to 0.5 Tesla within a magnetic field region at least partially overlapping with a test zone where the inspected object is to be located, to thereby magnetize nuclei in said object;
applying electromagnetic excitation signals in said test site to thereby affect the nuclei magnetization in the inspected object and concurrently generating magnetic gradients in three orthogonal directions there inside, to thereby cause spatially resolved nuclear spin echo signals from the inspected object, said electromagnetic excitation signals being applied with a predetermined time pattern;
receiving, with a predetermined time pattern, electromagnetic radiation responsive to the nuclear spin echo signals from the inspected object;
processing data corresponding to said received electromagnetic radiation, to extract therefrom data indicative of the spatially resolved nuclear spin echo signals from the inspected object, and using the extracted data to generate magnetic resonance images indicative of structural defects in said object.

19. A method according to claim 18 comprising:
displaying the magnetic resonance images in a display device; and
inspecting the displayed magnetic resonance images to indentify structural defects in said object.

20. A method according to claim 18 comprising:
extracting from the magnetic resonance images characteristic features associated with the structural defects in the inspected object;
identifying in said magnetic resonance images structural defects of the inspected object; and
outputting signals indicating that such structural defects have been identified.

21. A method according to claim 18 wherein the electromagnetic excitation signals are in a radiofrequency range of 5 to 25 MHz.

22. A method according to claim 18 comprising utilizing T₁-weighting and/or T₂-weighting techniques for contrasting the magnetic resonance images for specific defects.

23. A method according to claim 18 wherein the inspected object is reinforced by fibers, or granules, made from one or more materials selected a group consisting of: glass, boron, silicon carbide, carbon, and metal.

24. A method according to claim 18 wherein frequencies of the excitation signals are selected so as to affect magnetization of one or more nuclei selected from the following group: ¹H, ¹³C.

25. A method according to claim 18 wherein the inspection of the object is carried out without using contrast media or marker additives.

26. A method according to claim 18 comprising embedding in the inspected object nuclear probes having high natural abundance.

27. A method according to claim 26 wherein the nuclear probes comprise one or more isotopes selected from the group consisting of: ¹⁹F, ²⁷Al and ³¹P.

28. A method according to claim 18 wherein the electromagnetic excitation signals comprise one or more of the following pulse sequences: gradient echo, spin echo and inversion recovery.
